(19) United States
(12) Patent Application Publication
(10) Pub. No.: US 2017/0213925 A1
(43) Pub. Date: Jul. 27, 2017

(54) PHOTOVOLTAIC MODULES FOR RIGID CARRIERS

(71) Applicant: COMMISSARIAT A L'ENERGIE ATOMIQUE ET AUX ENERGIES ALTERNATIVES, Paris (FR)

(72) Inventors: Julien GAUME, La Tour Du Pin (FR); Stephane GUILLEREZ, Lepin Le Lac (FR); Lionel SICOT, Chambery (FR)

(73) Assignee: COMMISSARIAT A L'ENERGIE ATOMIQUE ET AUX ENERGIES ALTERNATIVES, Paris (FR)

(21) Appl. No.: 15/328,303

(22) PCT Filed: Jul. 27, 2015
(86) PCT No.: PCT/EP2015/067116

§ 371 Date: Jan. 23, 2017

(30) Foreign Application Priority Data
Jul. 28, 2014 (FR) 14 57277

(51) Int. Cl. H01L 31/048; H01L 31/05; H01L 31/18; H01L 31/049

(52) U.S. Cl. CPC H01L 31/0481; H01L 31/049; H01L 31/0504; H01L 31/1864; H01L 31/1876

(57) ABSTRACT

A photovoltaic module including at least a transparent first layer forming a front face of the photovoltaic module to receive a light flux, an assembly of plural photovoltaic cells arranged side by side and connected together electrically, an assembly encapsulating the photovoltaic cells, and a second layer fo ming a rear face of the photovoltaic module. The encapsulating assembly and assembly of photovoltaic cells is located between the first and second layers. The first layer includes at least a transparent polymer material and plural plates independent from one another, each plate located opposite at least one photovoltaic cell, to form a discontinuous front face for the photovoltaic module. Rigidity of the encapsulating assembly is defined by a Young's modulus of the encapsulation material greater than or equal to 75 MPa at ambient temperature and a thickness of the encapsulating assembly is between 0.4 and 1 mm.

### TECHNICAL DOMAIN

The present invention refers to the domain of photovoltaic modules, consisting of a set of photovoltaic cells connected together electrically, and in particular so-called “crystalline” photovoltaic cells, i.e. those based on silicon crystals or polycrystals.

The invention may be used for numerous applications, and is particularly suitable for applications requiring the use of flexible lightweight photovoltaic modules, resistant to impact and able to withstand high mechanical loads. It can thus be applied in particular on buildings such as private houses or industrial premises, for example as roofing material, or in the design of street furniture, such as for example street lighting, road signs or for recharging electric motor vehicles, or also for incorporation in traffic zones, for pedestrians and/or vehicles, such as road surfaces, cycling lanes, industrial platforms, squares, pavements, etc. This latter application is commonly referred to by the term “solar road”.

The invention thus proposes a photovoltaic module which is particularly suitable for application to rigid carriers, a photovoltaic structure assembly incorporating such a photovoltaic module, the use of such a photovoltaic module for its application to a rigid structure, as well as a process for the production of such a module or such a photovoltaic structure assembly.

### STATE OF THE PREVIOUS TECHNOLOGY

A photovoltaic module is an assembly of photovoltaic cells laid side by side between a first transparent layer, forming the front face of the photovoltaic module and a second layer forming the rear face of the photovoltaic module.

The first layer, forming the front face of the photovoltaic module is preferably transparent, to enable the photovoltaic cells to receive the light flux. Traditionally, it consists of a single plate of glass, around 3 mm thick. The second layer, forming the back face of the photovoltaic module on the other hand may be made of glass, metal or plastic, among others. It usually consists of a polymeric structure consisting of an electrically insulating polymer, such as polyethylene terephtalate (PET) or polyamide (PA), which may be protected with one or two layers of fluorinated polymer, such as polyvinyl fluoride (PVF) or polyvinylidene fluoride (PVDF), of around 300 μm thickness.

The photovoltaic cells may be connected together electrically in series by front and rear electrical contacts, called conductor links, consisting for example of strips of copper, located respectively against the front face (the face towards the front face of the photovoltaic module intended to receive the light flux) and the rear face (the face towards the rear face of the photovoltaic module) of each of the photovoltaic cells.

Additionally, the photovoltaic cells, located between the first and second layers forming respectively the front and rear faces of the photovoltaic module, are encapsulated. Conventionally, the encapsulant used corresponds to an elastomeric (or rubber) type polymer, and may for example consist of two layers (or films) of poly(ethylene vinyl-acetate) (EVA) between which the photovoltaic cells and link conductors of the cells are sealed. Each layer of EVA may be at least 0.3 mm thick and exhibit a Young's modulus less than or equal to 30 MPa at ambient temperature.

Again habitually, the process for producing the photovoltaic module includes a single rolling operation of the various layers described above, at a temperature greater than or equal to 140° C., or 150° C., for a period of at least 8 minutes, or even 15 minutes. Following this rolling operation, the two layers of EVA fuse together to form a single layer which totally encloses the photovoltaic cells.

Nevertheless, such previous state of the art photovoltaic modules are not entirely satisfactory and have certain disadvantages for at least certain of their applications.

For example, in the context of solar road type applications, a requirement has appeared to use roads or carriageways as a means of energy production during daytime, whether to supply buildings located nearby (companies, eco-districts, solar farms, private houses, etc.) or to feed into the electrical grid or traffic aids, for example.

Thus, first of all, the presence of a glass plate to form the front face of the photovoltaic module is not compatible with certain photovoltaic module applications which demand relative light weight and the possibility of shaping the module. On the contrary, previous state of the art designs using glass on the front face of the photovoltaic modules leads to a heavy module weight and limited integration possibilities.

For a solar road type application, the photovoltaic modules with a glass front face, on the one hand, are insufficiently flexible to accommodate the distortion of the road, of around 1 mm every 100 mm in both horizontal axes, along the width and length of the road. On the other hand, such photovoltaic modules are not able to withstand the static loading if they are bonded directly to the road surface. In other words, the roughness of the road surface can cause piercing of the photovoltaic cells from the rear face of the photovoltaic module, resulting in the possible risk of fracture of the photovoltaic cells.

Solutions have been considered by replacing the glass front face of the photovoltaic modules with plastic materials, whilst retaining the conventional architecture and production method for the photovoltaic modules. For example, patent application FR 2 955 051 A1 and international applications WO 2012/140585 A1 and WO 2011/028513 A2 describe the possibilities of alternatives to glass for the design of the front face of photovoltaic modules, among which the use of polymer sheets, of thickness less than or equal to 500 μm, such as polyvinylidene fluoride (PVDF), ethylene tetra fluoro ethylene (ETFE), polymethyl methacrylate (PMMA) or even polycarbonate (PC).

However, the simple replacement of the glass with a polymer layer, in order to achieve a lightweight and flexible photovoltaic module, generally results in greater vulnerability of the module to impact and mechanical loading, which is not acceptable for certain applications.

Moreover, in these examples of the previous state of the art, the front face (glass-free) of each photovoltaic module is continuous, i.e. it forms a single sheet or plate which covers the entire module. As a result, the flexibility of each photovoltaic module may be limited and in fact inadequate. Furthermore, this also raises the problem of accentuation of the expansion stresses between the different layers of the structure, which may lead to undesirable distortion or debonding at the interfaces of the structure, for example at the encapsulant/external layers interface.

Certain solutions have been put forward aimed at achieving a relative discontinuity of the front face of the photovoltaic module in order to obtain greater flexibility of the module and to better accommodate the differential expansion stresses. Thus, for example, patent application US 2014/0000683 A1 describes a method for encapsulating the photovoltaic cells individually. The encapsulated cells may then be connected together in order to achieve a flexible photovoltaic module. Also, patent application US 2014/0030841 A1 describes the mounting of a photovoltaic module on a flexible backing. The photovoltaic module consists of “sub-modules” made up of interconnected photovoltaic cells, each sub-module being electrically independent of its neighbouring sub-modules.

However, the solutions described above are not totally satisfactory in terms of flexibility, resistance to impact and mechanical loading, performance and cost of the photovoltaic modules, in particular for high stress applications which demand high mechanical strength.

### PRESENTATION OF THE INVENTION

There is therefore a need to propose an alternative design solution for a photovoltaic module to meet at least some of the constraints inherent in the applications targeted by the use of photovoltaic modules, in particular for improving the flexibility, the rigidity, the lightness and the resistance to impact and mechanical loading of photovoltaic modules.

This invention aims to at least partially address the needs mentioned above and the disadvantages inherent in the previous state of the art production.

The invention, for one of its aspects, is aimed at a photovoltaic module, which is suitable in particular for mounting on a rigid carrier, incorporating at least:
a first transparent layer forming the front face of the photovoltaic module intended to receive the light flux,
an assembly of several photovoltaic cells aligned side by side and connected together electrically,
an encapsulation of the assembly of several photovoltaic cells,
a second layer forming the rear face of the photovoltaic module, intended in particular to be mounted on a rigid backing, the encapsulated assembly and the assembly of several photovoltaic cells being located between the first and second layers, characterised by the fact that the first layer consists of at least a transparent polymer material and incorporates several plates which are independent from one another, each plate being located opposite at least one photovoltaic cell, such as to form a front face for the photovoltaic module which is discontinuous,
   and in that the rigidity of the encapsulated assembly is defined by the Young's modulus of the encapsulation material being greater than 75 MPa at ambient temperature and the thickness of the encapsulated assembly being between 0.4 and 1 mm.

Initially, i.e. before any rolling operation, the encapsulated assembly consists of two layers of encapsulation material, known as the core layers, between which the assembly of photovoltaic cells is encapsulated. However, following the rolling operation of the layers, the layers of the encapsulation material fuse together to form a single layer (or assembly) in which the photovoltaic cells are embedded. Prior to any rolling operation, each layer of the encapsulation material may thus exhibit a rigidity defined by the Young's modulus at ambient temperature of the encapsulation material greater than 75 MPa and a thickness of the layer of between 0.2 and 1 mm, or between 0.2 and 0.5 mm.

The encapsulated assembly of photovoltaic cells thus consists of two layers of encapsulation material, i.e. the layers of encapsulation material which prior to rolling are in direct contact with the photovoltaic cells.

The term “transparent” means that the material of the first layer forming the front face of the photovoltaic module is at least partially transparent to visible light, transmitting at least about 80% of that light.

Additionally, the expression “plates independent from one another”, signifies that the plates are located at a distance from one another, each forming a separate element which is independent from the first layer and from one another, superimposed on at least one photovoltaic cell. The association of all these plates thus forms the first layer with a discontinuous appearance.

Furthermore, the term “encapsulant” or “encapsulated”, refers to the assembly of several photovoltaic cells arranged in a given volume, for example hermetically sealed, at least in part formed by the layers of encapsulation material, bonded together after rolling.

The photovoltaic module may be applied to a rigid backing, which may, in a particular example of the use of the invention, be a traffic zone. The expression “traffic zone” refers to any zone intended for circulation of pedestrians and/or vehicles, such as for example a carriageway (or road), a motorway, a cycling lane, an industrial platform, a square, a pavement, this list being in no way comprehensive.

Moreover, the expression “ambient temperature”, is intended to mean a temperature between about 15 and 30° C.

Thanks to this invention, it is therefore possible to adopt an alternative solution for the design of a supple and relatively flexible photovoltaic module, and which is also strong enough to withstand impacts and the mechanical loads applied, in particular following application on a rigid backing. In particular, the use of a discontinuous front face may confer to the photovoltaic module according to the invention, a flexible characteristic which notably facilitates its application to a non flat backing, for example a curved backing. Additionally, the use of a highly rigid encapsulation material for the assembly encapsulating the photovoltaic cells ensures adequate protection for the photovoltaic cells against the risk of high mechanical loads or impacts, by limiting their bending, and so limiting the risk of fracture. In addition, the absence of any use of glass materials for the front face of the photovoltaic module ensures that the photovoltaic module according to the invention exhibits a lower weight than that of a photovoltaic module in accordance with the previous state of the art, typically by around 12 kg/m², according to the thickness of the different layers employed. Finally, the use of a discontinuous front face made of polymer material provides protection from the problems associated with thermal expansion when the photovoltaic module according to the invention is used outdoors. Indeed, as the thermal expansion is proportional to the dimensions of the first layer forming the front face of the module, the use of plates whose dimensions are close to those of the photovoltaic cells significantly limits the displacements induced by the thermal stresses which could generate delamination or uncontrolled deformation of the photovoltaic module.

The photovoltaic module according to the invention may additionally feature one or more of the following characteristics taken in isolation or in any technically possible combination.

The second layer, forming the rear face of the photovoltaic module may also be discontinuous. In other words, the second layer may also consist of several plates which are independent from one another, each plate being located opposite, i.e. superimposed on, at least one photovoltaic cell. The presence of a discontinuous rear face on the photovoltaic module according to the invention may for example enable further improvement of the flexibility of the module to facilitate its application to a rigid backing with a rough surface.

Also, even if the first layer forming the front face of the photovoltaic module according to the invention, and possibly the second layer forming the rear face of the module, feature a discontinuous appearance, the overall assembly of photovoltaic cells and the encapsulated assembly are advantageously continuous.

According to a particular production mode for the invention, each plate in the first layer, and possibly in the second layer, may be located opposite several photovoltaic cells. This may be the case in particular with photovoltaic cells whose dimensions are smaller than conventional photovoltaic cells, which are typically 156×156 mm.

Also, when a single photovoltaic cell is located opposite each plate in the first layer, and possibly the second layer, each plate may have dimensions at least equal to those of the photovoltaic cell on which it is superimposed.

The photovoltaic module is advantageously devoid of any glass first layer forming the front face of the module. Thus, as indicated previously, it is possible to improve the lightness and the incorporation capability of the photovoltaic module.

The encapsulation material forming the two layers of core encapsulation material for the encapsulated assembly may feature a Young's modulus at ambient temperature greater than or equal to 100 MPa, notably greater than or equal to 150 MPa, or even 200 MPa. It is in particular 220 MPa.

The encapsulated assembly may be formed from two layers of encapsulation material of identical or different thicknesses.

The second layer forming the rear face of the photovoltaic module may consist of at least one polymer material.

As a variant, the second layer forming the rear face of the photovoltaic module may consist of at least one composite material, in particular of the polymer/fibreglass type.

The second layer additionally, preferably, features a thermal expansion coefficient less than or equal to 20 ppm, and preferably less than or equal to 10 ppm.

The second layer forming the rear face of the photovoltaic module may or may not be transparent.

The rigidity of the second layer forming the rear face of the photovoltaic module may be defined by a rigidity factor, corresponding to the Young's modulus at ambient temperature of the material of the second layer multiplied by the thickness of the second layer, of between 5 and 15 GPa.mm.

Furthermore, the rigidity of the second layer forming the rear face of the photovoltaic module may be defined by the Young's modulus at ambient temperature of the material of the second layer greater than or equal to 1 GPa, or better, greater than or equal to 3 GPa, or even better, greater than or equal to 10 GPa, and a second layer thickness of between 0.2 and 3 mm.

In this way, the second layer forming the rear face of the photovoltaic module may exhibit a high rigidity, which may thus limit its flexibility. However, such high rigidity can reduce, or even prevent, piercing of the photovoltaic cells by the rear face of the module, i.e. the appearance of cracks and/or fractures of the photovoltaic cells, when the latter is applied to a backing exhibiting great surface roughness.

The spacing between two neighbouring, consecutive or adjacent photovoltaic cells, may be greater than or equal to 1 mm, in particular between 1 and 30 mm, and preferably greater than or equal to 3 mm, in particular between 10 and 20 mm.

The two neighbouring photovoltaic cells considered may be two neighbouring cells in the same series (known as the same “string”) or two neighbouring cells belonging respectively to two consecutive series of the assembly of photovoltaic cells.

The existence of large spacing between the photovoltaic cells may also enable the achievement of large spacing between the plates in the first layer forming the front face of the photovoltaic module. In this way, the discontinuous appearance of the front face of the module is accentuated, thus ensuring flexibility of the module to facilitate its application to the rigid backing.

Advantageously, the spacing between two neighbouring plates in the first layer, and possibly in the second layer, should be less than or equal to the spacing between two neighbouring photovoltaic cells.

According to a variant, the photovoltaic module may include an intermediate “damping” layer located between the first layer forming the front face of the photovoltaic module and the encapsulated assembly of several photovoltaic cells, enabling the assembly, particularly by bonding, of the first layer to the encapsulated assembly.

The intermediate layer may consist of at least one polymer material, in particular a thermoplastic or thermosetting polymeric resin.

The intermediate layer may appear for example in the from of a sheet or in liquid form. It may or not be adhesive, for example type PSA. It may be applied hot or at ambient temperature.

The rigidity of the intermediate layer may be defined by a Young's modulus of the intermediate layer material less than or equal to 50 MPa at ambient temperature and an intermediate layer thickness of between 0.01 and 1 mm.

The intermediate layer may in particular fulfil two main functions. On the one hand it may ensure the adhesion of the first layer forming the front face of the photovoltaic module to the encapsulated assembly in the event that the two layers are chemically incompatible. On the other hand, it may enable the creation within the photovoltaic module of a relatively supple “damping” layer which improves the resistance of the module to impact and to mechanical loading.

This intermediate layer may be optional, in particular it may be absent when there is chemical compatibility between the first layer forming the front face of the photovoltaic module and the encapsulating assembly.

The photovoltaic module may additionally include an adhesive layer located between the second layer forming the rear face of the photovoltaic module and the assembly encapsulating the several photovoltaic cells, enabling the assembly, notably by bonding, of the second layer to the encapsulating assembly.

The “adhesive layer”, here refers to a layer, which once the photovoltaic module has been produced, enables the second layer to adhere to the encapsulating assembly. This layer thus ensures the chemical compatibility and adhesion between the encapsulating assembly and the rear face.

Additionally, the thickness of the first layer forming the front face of the photovoltaic module may be greater than or equal to 0.1 mm, notably between 0.5 and 6 mm.

Moreover, the invention is intended, according to another of its aspects, as a photovoltaic structure assembly, including :
a rigid backing,
a photovoltaic module as defined above, and
a mounting layer, notably by bonding, located between the rigid backing and the photovoltaic module, enabling the adhesion of the photovoltaic module to the rigid backing.

The rigid backing may exhibit surface roughness.

According to a variant of the invention, the attachment layer may consist of a bituminous adhesive.

Use of the attachment layer provides a reinforced rear face for the photovoltaic module, thus avoiding the risk of piercing the photovoltaic cells through the rear face if the rigid backing exhibits high surface roughness and the photovoltaic module is subjected to an impact or a high mechanical load. Indeed, the interface between the rear face of the module and the rigid backing may thus be filled with a protection binder.

Additionally, the invention is also intended, according to another of its aspects of use, for application to a rigid backing of a photovoltaic module including at least:
a first transparent layer forming the front face of the photovoltaic module intended to receive the light flux,
an assembly of several photovoltaic cells arranged side by side and connected together electrically,
an assembly encapsulating the set of photovoltaic cells,
a second layer forming the rear face of the photovoltaic module, the encapsulating assembly and the assembly of several photovoltaic cells being located between the first and second layers,
   The first layer consisting of at least one transparent polymer material featuring shock nanostructured polymethyl methacrylate (PMMA), and including several plates independent from one another, each plate being located opposite at least one photovoltaic cell, such as to form a discontinuous front face for the photovoltaic module, and the rigidity of the encapsulating assembly being defined by a Young's modulus of the encapsulation material greater than or equal to 75 MPa at ambient temperature and with an encapsulating assembly thickness of between 0.4 and 1 mm,
   the photovoltaic module being applied to the rigid backing via an attachment layer.

Furthermore, the invention has another objective, according to another of its aspects, a production process for the photovoltaic module as defined above or a photovoltaic structure assembly as defined above, including at least the following two successive stages:
a) hot rolling at a temperature in excess of 150° C., of all the constituent layers of the photovoltaic module apart from the first layer forming the front face of the photovoltaic module and a possible intermediate so-called “damping” layer , located between the first layer and the assembly encapsulating the several photovoltaic cells,
b) rolling at a temperature less than or equal to 150° C., or better 125° C., for example ambient temperature, of the first layer forming the front face of the photovoltaic module, and the possible intermediate layer, on the constituent layers of the photovoltaic module rolled together during the first stage a).

During the first rolling stage a), the constituent layers of the photovoltaic module concerned thus form the assembly of several photovoltaic cells, the encapsulating assembly and the second layer forming the rear face of the photovoltaic module.

The possible intermediate so-called “damping” layer is intended to facilitate bonding of the first layer forming the front face of the module to the other layers. This intermediate layer is optional. In particular, it may not be necessary in the event of chemical compatibility between the first layer forming the front face of the module and the encapsulating assembly.

Advantageously, the use of at least two rolling stages in the process according to the invention to produce the photovoltaic module may overcome any problems associated with thermal expansion which could be encountered due to the use of a front face of the module made of polymer material.

Indeed, certain layers of the photovoltaic module have to be rolled at a temperature greater than or equal to 140° C., or even 150° C., but rolling at such a temperature in a single stage, in accordance with the previous state of the art, of all the layers of the module, including that forming the front face of the module, may result in uncontrolled deformation and severe delamination of the front face of the photovoltaic module due to the generation of excessive mechanical stresses.

Also, the presence of at least a second rolling stage at a lower temperature than the first stage, for rolling the front face of the photovoltaic module, possibly combined with the presence of an intermediate so-called “damping” layer enabling bonding of the front face of the module to the encapsulation material and damping the thermal stresses, could limit, or even eliminate, the thermal expansion.

Alternatively, the invention has a further objective, according to one of its aspects, a production process for a photovoltaic module as defined above or a photovoltaic structure assembly as defined above, including the following single stage:
c) hot rolling at a temperature greater than or equal to 150° C. of all the constituent layers of the photovoltaic module.

In order to produce a photovoltaic structure assembly as defined above, stages a) and b), or stage c), may be followed by stage d) for attachment of the photovoltaic module to a rigid backing to form the photovoltaic structure, using an attachment layer for the photovoltaic structure assembly, consisting for example of a bituminous adhesive.

As already indicated, the thickness of the encapsulating assembly may be between 0.4 and 1 mm, as a result of the combination by rolling of at least two layers of encapsulation material, each of thickness between 0.2 and 0.5 mm. These two layers of encapsulation material may be of different thicknesses.

The photovoltaic module, photovoltaic structure assembly and the process according to the invention may include any of the characteristics mentioned above, taken in isolation or in any technically possible combination with other characteristics.

### BRIEF DESCRIPTION OF THE DRAWING

The invention may be better understood by the detailed description below, of a non exclusive example of its use, together with examination of the single diagrammatic and partial figure, of the drawing in the appendix, illustrating, in section and exploded view, an example of the use of a photovoltaic structure assembly incorporating a photovoltaic module in accordance with the invention.

In this single FIGURE, the different parts represented are not necessarily drawn at the same scale, in order to improve the legibility of the figure.

### DETAILED DESCRIPTION OF A PARTICULAR PRODUCTION METHOD

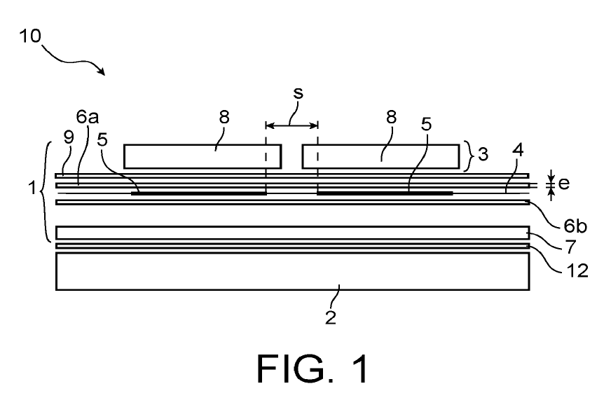

Reference is made below to FIG. 1, which illustrates in section and exploded view an example of a photovoltaic structure assembly 10 incorporating a photovoltaic module 1 in accordance with the invention.

It should be noted that FIG. 1 corresponds to an exploded view of the photovoltaic structure assembly 10 prior to the rolling stages of the process according to the invention. Once the rolling stages have been performed, the different layers are in fact superimposed on one another, but also slightly deformed such that at least the plates 8 of the first layer 3 are embedded in the assembly formed by the intermediate layer 9 and the encapsulating assembly 6a, 6b which are deformed. The rolling stages ensure hot compression in vacuum. According to the thickness of the various layers, the plates 8 may or may not be flush with the photovoltaic module 1, the material of the intermediate layer 9 and possibly that of the encapsulating assembly 6a, 6b which may at least partly fill the spaces between the plates 8.

As already explained, the photovoltaic module 1 in accordance with the invention is designed to be sufficiently flexible to enable its attachment, in particular by bonding, to a rigid backing 2, which may exhibit surface roughness, in other words not necessarily flat and smooth. Additionally, the photovoltaic module 1 in accordance with the invention is also intended to withstand static or dynamic pressures of up to 1500 kN/m², or even 5000 kN/m². The rigid backing 2 should preferably by sufficiently rigid not to deform when subjected to the same stress as that applied to photovoltaic module 1. It may for example by formed by a roof covering, made of concrete or sheet metal, among others.

As can be seen in FIG. 1, the photovoltaic module 1 incorporates a transparent first layer 3 forming the front face of module 1 intended to receive the light flux, an encapsulating assembly 6a, 6b, obtained by fusion of two layers of encapsulation material, top 6a and bottom 6b, an assembly 4 of photovoltaic cells 5 sandwiched between the top 6a and bottom 6b layers of encapsulation material, and a second layer 7 forming the rear face of the photovoltaic module 1 intended for bonding to a rigid backing 2.

The two layers of encapsulation material 6a and 6b forming the encapsulating assembly, as well as the possible intermediate layer 9 described subsequently, form a relatively supple structure which may consist of a single or several materials in the event of chemical incompatibility.

According to the invention, the first layer 3 consists of a transparent polymer and incorporates an assembly of plates 8 which are independent from one another, each plate 8 being located opposite a photovoltaic cell 5, such as to form the discontinuous front face of the photovoltaic module 1.

The transparent polymer material of the first layer 3 may for example be chosen between polycarbonate (PC), polymethyl methacrylate (PMMA), ethylene tetra fluoro ethylene (ETFE), or polyvinylidene fluoride (PVDF), among others. Additionally, the thickness of the first layer 3 may be greater than 0.1 mm, and ideally between 0.5 and 6 mm. In this example, the first layer 3 thus consists of several plates 8, of dimensions 162 ×162 mm, of 3 mm thick PMMA.

Additionally, the photovoltaic cells 5 are connected together electrically spaced apart by distance s between adjacent cells 5, of between 1 and 30 mm. The photovoltaic cells 5 may be so-called “crystalline” cells, i.e. based on crystals or polycrystals of silicon, with a homojunction or heterojunction, and of thickness less than or equal to 250 μm. Additionally, in this example, each plate 8 overlaps the subjacent photovoltaic cell 5 on each side by a distance of about 3 mm, such that the spacing between two plates 8 is in this case equal to the spacing s between 2 adjacent cells 5 less about 2 times 3 mm, i.e. about 6 mm.

Moreover, the rigidity of each layer of encapsulation material 6a and 6b is defined by a Young's modulus E at ambient temperature of the encapsulation material greater than or equal to 50 MPa, or 75 MPa, or even 100 MPa, preferably greater than or equal to 200 MPa, and a thickness e of layers 6a, 6b of between 0.2 and 1 mm.

The layers of encapsulation material 6a and 6b form an encapsulating assembly preferably chosen to be an ionomer such as the ionomer marketed under the name of jurasol® ionomer type DG3 by the Jura-plast company or the ionomer marketed under the name of PV5414 by Du Pont, featuring a Young's modulus at ambient temperature greater than or equal to 200 MPa and a thickness of about 500 μm.

The second layer 7 forming the rear face of the photovoltaic module 1 on the other hand consists of a polymer material such as thermosetting resins such as epoxy based resins, transparent or not, or a composite material, for example of the polymer/fibreglass type. In this example, the second layer 7 consists of a composite material of polymer/fibreglass type, in particular a polypropylene and fibreglass based fabric with a fibreglass content of 60% by weight, such as Thermopreg® fabric P-WRt-1490-PP60W marketed by the Owens Corning Vetrotex company, around 1 mm thick and whose Young's modulus at ambient temperature is around 12 GPa.

Additionally, although it is not shown, a possible adhesive, or compatibilising layer (its presence being justified in the event of chemical incompatibility), may be located between the second layer 7 forming the rear face of the photovoltaic module 1 and the encapsulating assembly formed by the two layers of encapsulation material 6a and 6b on either side of the assembly 4 of photovoltaic cells 5. This compatibilising layer may enable bonding of the second layer 7 to the bottom layer of encapsulation material 6b. In the event of use of Thermopreg° fabric P-WRt-1490-PP60W for the second layer 7, the compatibilising layer may preferably be chosen to be a film of type Mondi TK41001 of approximately 50 μm thickness.

Also, as can be seen in FIG. 1, the photovoltaic module 1 also incorporates an intermediate so-called “damping” layer 9 located between the first layer 3 and the encapsulating assembly formed by the two layers of encapsulation material 6a and 6b on either side of the assembly 4 of photovoltaic cells 5.

The intermediate layer 9 is optional and is essentially useful in the event of chemical incompatibility between the first layer 3 and the top encapsulation material 6a.

The intermediate layer 9 enables bonding of the first layer 3 to the top encapsulation material 6a.

The intermediate layer 9 for example consists of a standard encapsulant used in the photovoltaic domain, such as the ethylene-vinyl-acetate (EVA) copolymer, a polyolefine, silicone, polyurethane thermoplastic, polyvinyl butyral, among others. It may also consist of a liquid resin acrylic type, silicone or polyurethane, single or two-part, cross-linked at high temperature, photochemically or at low temperature (i.e. ambient temperature). It may also consist of a pressure-sensitive adhesive of type PSA (“Pressure-Sensitive Adhesive”).

In this example, the intermediate layer 9 consists of a thermoplastic film, in particular thermoplastic polyurethane also known as TPU, such as type TPU Dureflex® A4700 marketed by Bayer or PX1001 marketed by the American Polyfilm company, of thickness equal to about 380 μm.

The intermediate layer 9 fulfils two main functions. Firstly, it ensures the adhesion of the first layer 3 to the top encapsulation material 6a in the event that the two layers are not chemically compatible. Secondly, it enables the establishment of a “damping” layer for the photovoltaic module 1 providing a certain flexibility which enhances the resistance of the module 1 to impact and to mechanical loads.

Additionally, the photovoltaic structure assembly 10 in accordance with the invention shown in FIG. 1 also incorporates a rigid backing 2. The rigid backing 2 may be of any type of material. It may be flat or curved, smooth or rough.

In order to enable bonding of the photovoltaic module 1 to the rigid backing 2, assembly 10 also includes an attachment layer 12. This attachment layer 12 consists of an adhesive to bond module 1 to the rigid backing 2.

A production process is described below to produce photovoltaic module 1 and a photovoltaic structure assembly 10 in accordance with the invention.

The process includes a first stage a) of hot rolling at a temperature of about 170° C. and in vacuum (pressure less than or equal to 10 mbar) of the constituent layers 6a, 4, 6b and 7 of the photovoltaic module 1 apart from the first layer 3 and the intermediate layer 9. This first hot rolling stage a) is conducted for about 15 minutes in order to obtain a “laminate” of encapsulated photovoltaic cells 5. The rolling parameters, such as the temperature, the time and the pressure, are however dependent on the encapsulating material used.

Next, the process includes a second stage b) of hot rolling at a temperature of about 125° C. and in vacuum of the “laminate” obtained during the first stage a) with the first layer 3 forming the front face of the photovoltaic module 1 together with the intermediate layer 9. This second stage b) is conducted for about 30 minutes such as to obtain the photovoltaic module 1 according to the invention. Prior to execution of this second stage b), the plates 8 of the first layer 3 may advantageously be treated with Corona treatment equipment in order to achieve a surface energy level greater than or equal to 48 dyn/cm.

These first a) and second b) rolling stages are then followed by an attachment stage for the photovoltaic module 1 to the rigid backing 2 which thus forms the photovoltaic structure assembly.

In consequence, the photovoltaic module 1 in accordance with the invention may exhibit enhanced mechanical strength, suitable for constraining applications in terms of mechanical loading, such as the type of solar road, whilst at the same time providing flexibility in parts due to the presence of a discontinuous front face 3, which enables it to adopt different shapes to adapt to different types of surfaces, for example uneven or imperfectly flat. Additionally, the presence of a reinforced rear face 7 may improve the resistance to piercing of this rear face 7 of module 1, such piercing could be the result of the roughness of the support 2 on which module 1 is applied and which could cause cracking of the photovoltaic cells 5 of the photovoltaic module 1.

Naturally, the invention is not limited to the example of use described above. Various modifications may be introduced by experienced operators.

The expression “including one” should be taken as synonymous with “including at least one”, except if specified otherwise.

1-15. (canceled)

16. A photovoltaic module comprising:
a transparent first layer forming a front face of the photovoltaic module configured to receive the light flux;
an assembly of plural photovoltaic cells arranged side by side and connected together electrically;
an encapsulated assembly of the plural photovoltaic cells;
a second layer forming a rear face of the photovoltaic module, the encapsulating assembly and the assembly of plural photovoltaic cells being located between the first and second layers;
wherein the first layer includes at least a transparent polymer material and plural plates independent from one another, each plate being located opposite at least one photovoltaic cell, to form a discontinuous front face for the photovoltaic module, and
wherein rigidity of the encapsulating assembly is defined by a Young's modulus of the encapsulation material greater than or equal to 75 MPa at ambient temperature and a thickness of the encapsulating assembly is between 0.4 and 1 mm.

17. A module in accordance with claim 16, wherein the encapsulation material of the layers forming the encapsulating assembly exhibit a Young's modulus at ambient temperature greater than or equal to 100 MPa.

18. A module according to claim 16, wherein the second layer forming the rear face of the photovoltaic module includes at least one polymer material.

19. A module according to claim 16, wherein the second layer foiining the rear face of the photovoltaic module includes at least one composite material.

20. A module according to claim 16, wherein rigidity of the second layer foil ling the rear face of the photovoltaic module is defined by a rigidity factor, corresponding to Young's modulus at ambient temperature of the material of the second layer multiplied by thickness of the second layer, of between 5 and 15 GPa.mm.

21. A module according to claim 16, wherein spacing between two adjacent photovoltaic cells is greater than or equal to 1 mm.

22. A module according to claim 16, further comprising an intermediate layer located between the first layer forming the front face of the photovoltaic module and the encapsulating assembly of plural photovoltaic cells, enabling assembly of the first layer to the encapsulating assembly.

23. A module according to claim 22, wherein the intermediate layer includes at least one polymer material.

24. A module according to claim 22, wherein rigidity of the intermediate layer is defined by the Young's modulus of the material of the intermediate layer less than or equal to 50 MPa at ambient temperature and a thickness of the intermediate layer of between 0.01 and 1 mm.

25. A module according to claim 16, wherein the thickness of the first layer forming the front face of the photovoltaic module is greater than or equal to 0.1 mm.

26. A photovoltaic structure assembly, comprising:
a rigid backing;
a photovoltaic module according to claim 16; and
an attachment layer located between the rigid backing and the photovoltaic module, enabling adhesion of the photovoltaic module to the rigid backing.

27. Use, for its application to a rigid backing, of a photovoltaic module comprising:
a transparent first layer forming a front face of the photovoltaic module configured to receive light flux;
an assembly of plural photovoltaic cells arranged side by side and connected together electrically;
an assembly encapsulating the plural photovoltaic cells;
a second layer forming a rear face of the photovoltaic module, the encapsulating assembly and the assembly of plural photovoltaic cells being located between the first and second layers;
the first layer including at least one transparent polymer material including plural plates independent from one another, each plate being located opposite at least one photovoltaic cell, to form a discontinuous front face for the photovoltaic module; and
rigidity of the encapsulating assembly being defined by a Young's modulus of the encapsulation material greater than or equal to 75 MPa at ambient temperature and a thickness of the encapsulating assembly is between 0.4 and 1 mm,
the photovoltaic module being applied to the rigid backing via an attachment layer.

28. A process for production of a photovoltaic module according to claim 16, comprising:
a) hot rolling at a temperature greater than 150° C. of constituent layers of the photovoltaic module apart from the first layer forming the front face of the photovoltaic module and a possible intermediate layer located between the first layer and the encapsulating assembly of plural photovoltaic cells;
b) rolling at a temperature strictly less than or equal to 150° C., of the first layer forming the front face of the photovoltaic module, and any intermediate layer, to the constituent layers of the photovoltaic module rolled together during a).

29. A process for production of a photovoltaic module according to claim 16, comprising:
a) hot rolling at a temperature greater than or equal to 150° C. of all constituent layers of the photovoltaic module.

30. A process for production of a photovoltaic structure assembly according to claim 26, comprising:
a) hot rolling at a temperature greater than 150° C. of constituent layers of the photovoltaic module apart from the first layer forming the front face of the photovoltaic module and a possible intermediate layer located between the first layer and the encapsulating assembly of plural photovoltaic cells, b) rolling at a temperature strictly less than or equal to 150° C., of the first layer forming the front face of the photovoltaic module, and any intermediate layer, to the constituent layers of the photovoltaic module rolled together during a), and d) attachment of the photovoltaic module to a rigid backing to form the photovoltaic structure assembly, via the attachment layer of the photovoltaic structure assembly.
